(19) United States
(12) Patent Application Publication
(10) Pub. No.: US 2024/0395965 A1
(43) Pub. Date: Nov. 28, 2024

(54) PHOTODETECTORS WITH ONE OR MORE CONFINING FEATURES

(71) Applicant: GlobalFoundries U.S. Inc., Maita, NY (US)

(72) Inventor: Yusheng Bian, Ballston Lake, NY (US)

(21) Appl. No.: 18/200,683

(22) Filed: May 23, 2023

(51) Int. Cl. H01L 33/00; H01L 33/48; H01L 33/50; H01L 33/52

(52) U.S. Cl. CPC H01L 33/0041; H01L 33/486; H01L 33/50; H01L 33/52

(57) ABSTRACT

Structures including a photodetector and methods of forming a structure including a photodetector. The structure comprises a photodetector including a pad and a semiconductor layer positioned on the pad. The semiconductor layer has a sidewall, the pad comprises a semiconductor material, and the pad includes a top surface and a side edge. The structure further comprises a waveguide core including a tapered section adjacent to the side edge of the pad, and a confining feature in the pad adjacent to the sidewall of the semiconductor layer. The confining feature extends below the top surface of the pad, and the confining feature comprises a dielectric material.

### BACKGROUND

The disclosure relates to semiconductor device fabrication and integrated circuits and, more specifically, to structures including a photodetector and methods of forming a structure including a photodetector.

Photonics chips are used in many applications and systems including, but not limited to, data communication systems and data computation systems. A photonics chip includes a photonic integrated circuit comprised of optical components, such as modulators, polarizers, and optical couplers, that are used to manipulate light received from a light source, such as a laser or an optical fiber.

Photonics chips may include a photodetector that converts light, which may be modulated as an optical signal, into an electrical signal. The design of a photodetector may require a tradeoff between different performance metrics. For example, shrinking the intrinsic region of a photodetector may improve photodetector bandwidth at the expense of sacrificing photodetector responsivity.

Improved structures including a photodetector and methods of forming a structure including a photodetector are needed.

### SUMMARY

In an embodiment of the invention, a structure for a photonics chip is provided. The structure comprises a photodetector including a pad and a semiconductor layer positioned on the pad. The semiconductor layer has a sidewall, the pad comprises a semiconductor material, and the pad includes a top surface and a side edge. The structure further comprises a waveguide core including a tapered section adjacent to the side edge of the pad, and a confining feature in the pad adjacent to the sidewall of the semiconductor layer. The confining feature extends below the top surface of the pad, and the confining feature comprises a dielectric material.

In an embodiment of the invention, a method of forming a structure for a photonics chip is provided. The method comprises forming a photodetector that includes a pad comprising a semiconductor material, forming a semiconductor layer that is positioned on the pad, forming a waveguide core that includes a tapered section adjacent to a side edge of the pad, and forming a confining feature in the pad adjacent to a sidewall of the semiconductor layer. The confining feature extends below a top surface of the pad, and the confining feature comprises a dielectric material.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals refer to like features in the various views.

FIG. 1 is a top view of a structure at an initial fabrication stage of a processing method in accordance with embodiments of the invention.

FIG. 2 is a cross-sectional view taken generally along line 2-2 in FIG. 1.

FIG. 2A is a cross-sectional view taken generally along line 2A-2A in FIG. 1.

FIG. 3 is a top view of the structure at a fabrication stage subsequent to FIG. 1.

FIG. 4 is a cross-sectional view taken generally along line 4-4 in FIG. 3.

FIG. 4A is a cross-sectional view taken generally along line 4A-4A in FIG. 3.

FIGS. 5, 5A are cross-sectional views of the structure at a fabrication stage subsequent to FIGS. 3, 4, 4A.

FIG. 6 is a cross-sectional view of a structure in accordance with alternative embodiments of the invention.

FIG. 7 is a cross-sectional view of a structure in accordance with alternative embodiments of the invention.

FIG. 8 is a cross-sectional view of a structure in accordance with alternative embodiments of the invention.

FIG. 9 is a cross-sectional view of a structure in accordance with alternative embodiments of the invention.

FIG. 10 is a top view of a structure in accordance with alternative embodiments of the invention.

FIG. 11 is a top view of a structure in accordance with alternative embodiments of the invention.

FIG. 12 is a top view of a structure in accordance with alternative embodiments of the invention.

FIG. 13 is a top view of a structure in accordance with alternative embodiments of the invention.

FIG. 14 is a top view of a structure in accordance with alternative embodiments of the invention.

FIG. 15 is a cross-sectional view of a structure in accordance with alternative embodiments of the invention.

FIG. 16 is a cross-sectional view of a structure in accordance with alternative embodiments of the invention.

FIG. 17 is a cross-sectional view of a structure in accordance with alternative embodiments of the invention.

FIG. 18 is a cross-sectional view of a structure in accordance with alternative embodiments of the invention.

### DETAILED DESCRIPTION

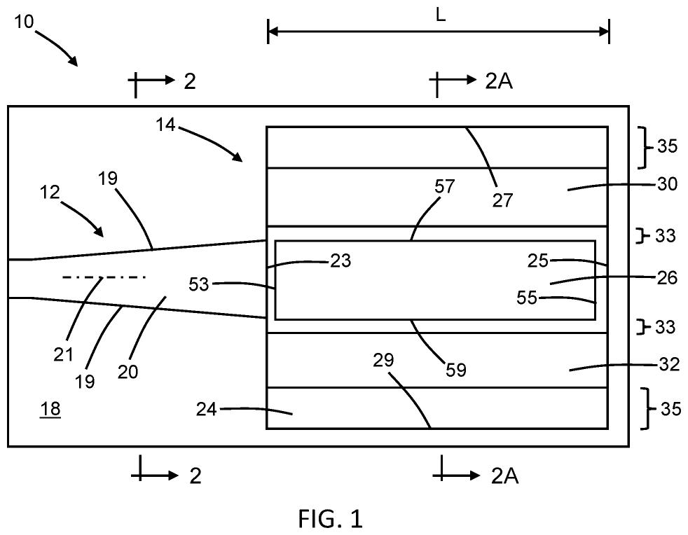

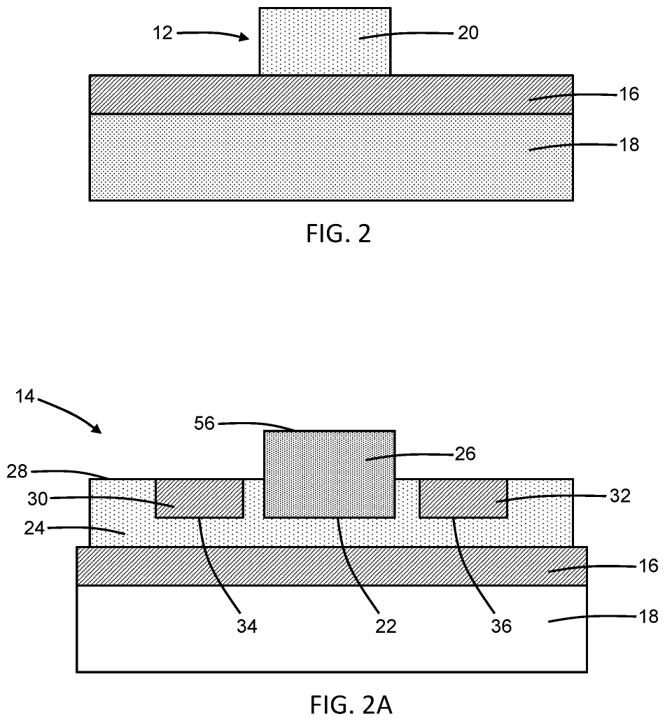

With reference to FIGS. 1, 2, 2A and in accordance with embodiments of the invention, a structure 10 includes a waveguide core 12 and a photodetector 14 that are positioned on, and above, a dielectric layer 16 and a semiconductor substrate 18. In an embodiment, the dielectric layer 16 may be comprised of a dielectric material, such as silicon dioxide, and the semiconductor substrate 18 may be comprised of a semiconductor material, such as single-crystal silicon. In an embodiment, the dielectric layer 16 may be a buried oxide layer of a silicon-on-insulator substrate, and the dielectric layer 16 may separate the waveguide core 12 and the photodetector 14 from the semiconductor substrate 18.

The waveguide core 12 includes a tapered section 20 that is positioned adjacent to the photodetector 14. The tapered section 20 of the waveguide core 12 has opposite sidewalls 19, and the tapered section 20 may extend along a longitudinal axis 21. The photodetector 14 includes a pad 24 having side edges 23, 25, 27, 29 and a semiconductor layer 26 that is disposed on the pad 24 interior of the side edges 23, 25, 27, 29. The tapered section 20 may terminate at the side edge 23 of the pad 24 at the intersections between the sidewalls 19 and the side edge 23.

The semiconductor layer 26 may have a sidewall 53 that is positioned adjacent to the side edge 23 of the pad 24, a sidewall 55 that is positioned adjacent to the side edge 25 of the pad 24, a sidewall 57 that is positioned adjacent to the side edge 27 of the pad 24, and a sidewall 59 that is positioned adjacent to the side edge 29 of the pad 24. The tapered section 20 of the waveguide core 12 is positioned adjacent to the sidewall 53 of the semiconductor layer 26. In an embodiment, the side edge 23 of the pad 24 may be positioned between the tapered section 20 and the sidewall 53 of the semiconductor layer 26.

The tapered section 20 may have a width dimension that increases with decreasing distance along the longitudinal axis 21 from the side edge 23 of the pad 24. In an embodiment, the width dimension of the tapered section 20 may increase linearly with decreasing distance from the side edge 23. In an alternative embodiment, the width dimension of the tapered section 20 may vary based on a non-linear function, such as a quadratic function, a cubic function, a parabolic function, a sine function, a cosine function, a Bezier function, or an exponential function. In an embodiment, the tapered section 20 may include a single stage of tapering characterized by a taper angle. In an alternative embodiment, the tapered section 20 may taper in multiple stages each characterized by a different taper angle.

In an alternative embodiment, the longitudinal axis 21 of the tapered section 20 may be angled to reduce optical return loss from the side edge 23 of the pad 24 and the sidewall 53 of the semiconductor layer 26. In an alternative embodiment, the tapered section 20 of the waveguide core 12 may be tapered in the height dimension as well as tapered in the width dimension. For example, the height dimension of the tapered section 20 may increase with decreasing distance from the side edge 23 of the pad 24. In an alternative embodiment, the semiconductor substrate 18 may include a cavity or undercut beneath all or part of the tapered section 20 of the waveguide core 12.

In an embodiment, the waveguide core 12 and the pad 24 of the photodetector 14 may be comprised of a material having a refractive index that is greater than the refractive index of silicon dioxide. In an embodiment, the waveguide core 12 and the pad 24 of the photodetector 14 may be comprised of a semiconductor material. In an embodiment, the waveguide core 12 and the pad 24 of the photodetector 14 may be comprised of single-crystal silicon. The waveguide core 12 and the pad 24 of the photodetector 14 may be formed by patterning a layer comprised of their constituent material with lithography and etching processes. In an embodiment, the waveguide core 12 and the pad 24 of the photodetector 14 may be formed by patterning the semiconductor material (e.g., single-crystal silicon) of a device layer of a silicon-on-insulator substrate. In an embodiment, the tapered section 20 of the waveguide core 12 may be a stacked waveguide core that includes, for example, a tapered section of another waveguide core comprised of a different material that is disposed over the tapered section 20.

The semiconductor layer 26 may be comprised of a light-absorbing material that generates charge carriers from absorbed light by the photoelectric effect. In an embodiment, the semiconductor layer 26 may be comprised of a material having a composition that includes germanium. In an embodiment, the semiconductor layer 26 may be comprised of intrinsic germanium. The semiconductor layer 26 may be formed by an epitaxial growth process. In an embodiment, the semiconductor layer 26 may be epitaxially grown inside a trench 22 that is patterned in the pad 24 such that the semiconductor layer 26 includes a lower portion arranged below the top surface 28 of the pad 24 and an upper portion that projects above the top surface 28 of the pad 24. The upper portion of the semiconductor layer 26 may have a top surface 56.

A confining feature 30 and a confining feature 32 may be formed in different portions of the pad 24. The confining feature 30 may be formed in a trench 34 that is defined as a notch in the pad 24, and the confining feature 32 may be formed in a trench 36 that is defined as a notch in the pad 24. The confining features 30, 32 may be comprised of a dielectric material, such as silicon dioxide, that is deposited inside the trenches 34, 36 and planarized. The trench 22 is disposed in a lateral direction between the trench 34 and the trench 36, and the semiconductor layer 26 inside the trench 22 is disposed in a lateral direction between the confining feature 30 in the trench 34 and the confining feature 32 in the trench 36.

The confining feature 30 is positioned adjacent to the sidewall 57 of the semiconductor layer 26, and the confining feature 32 is positioned adjacent to the sidewall 59 of the semiconductor layer 26 that is opposite to the sidewall 57. The confining feature 30 is spaced from the sidewall 57 of the semiconductor layer 26 and the confining feature 32 is spaced from the sidewall 59 of the semiconductor layer 26 such that respective portions 33 of the pad 24 are disposed between the confining features 30, 32 and the semiconductor layer 26. Similarly, respective portions 35 of the pad 24 are disposed between the confining features 30, 32 and the side edges 27, 29 of the pad 24. The confining feature 30 is disposed in the pad 24 between the side edge 27 and the sidewall 57, and the confining feature 32 is disposed in the pad 24 between the side edge 29 and the sidewall 59. The width of the portion 33 and/or the portion 35 between the side edge 27 of the pad 24 and the sidewall 57 of the semiconductor layer 26 may be altered by modifying the width and/or location of the confining feature 30. The width of the portion 33 and/or the portion 35 between the side edge 29 of the pad 24 and the sidewall 59 of the semiconductor layer 26 may be altered by modifying the width and/or location of the confining feature 32. The trench 22 has a length L, which represents the largest dimension of the trench 22, that may be oriented parallel to the sidewalls 57, 59 of the semiconductor layer 26.

The confining features 30, 32 and trenches 34, 36 penetrate partially through the thickness of the pad 24 in a vertical direction toward the dielectric layer 16. In an embodiment, the trenches 34, 36 may be patterned in the pad 24 when the trench 22 is patterned in the pad 24 such that the trenches 34, 36 and the trench 22 extend to equal depths relative to the top surface 28. In an embodiment, each of the trenches 34, 36 may extend to a uniform depth relative to the top surface 28 of the pad 24. In an embodiment, the confining features 30, 32 and trenches 34, 36 may extend fully from the side edge 23 of the pad 24 to the opposite side edge 25 of the pad 24.

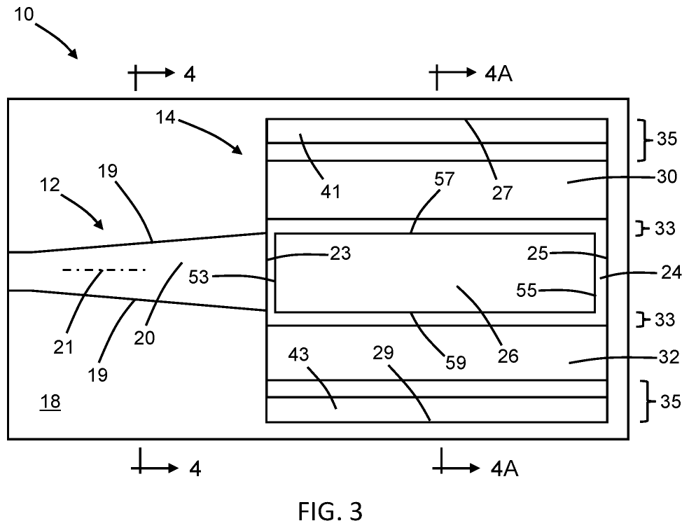

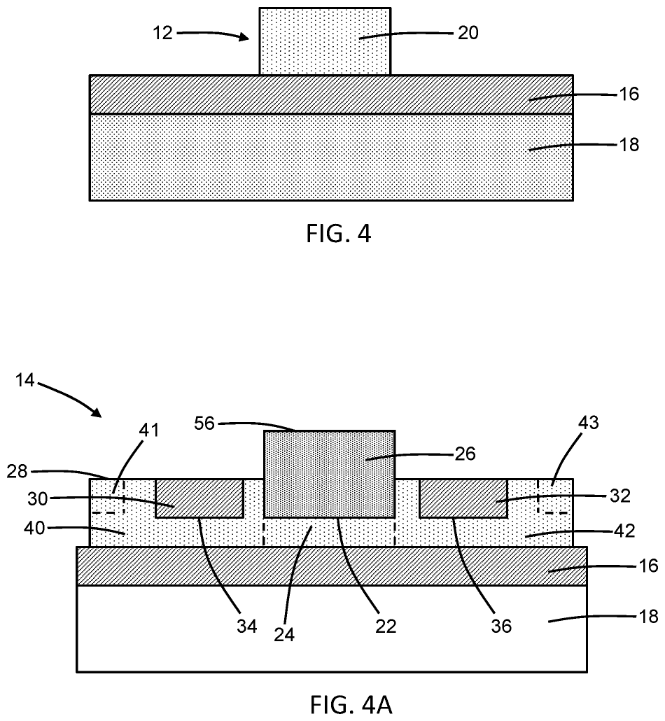

With reference to FIGS. 3, 4, 4A in which like reference numerals refer to like features in FIGS. 1, 2, 2A and at a subsequent fabrication stage, the structure 10 may include a doped region 40 and a doped region 42 that are formed in respective portions of the pad 24. The doped regions 40, 42, which differ in conductivity type, may extend through the entire thickness of the pad 24 to the underlying dielectric layer 16. The semiconductor layer 26 is laterally positioned between the doped region 40 and the doped region 42. The doped region 40 and the doped region 42 may be arranged adjacent to the opposite sidewalls 57, 59 of the semiconductor layer 26 to respectively define an anode and a cathode of the photodetector 14.

The doped region 40 may be formed by, for example, ion implantation with an implantation mask having an opening that determines the implanted area of the pad 24. The implantation mask may include a layer of photoresist applied by a spin-coating process, pre-baked, exposed to light projected through a photomask, baked after exposure, and developed with a chemical developer to define the opening over the area of the pad 24 to be implanted. The implantation conditions (e.g., ion species, dose, kinetic energy) may be selected to tune the electrical and physical characteristics of the doped region 40. The implantation mask may be stripped after forming the doped region 40. In an embodiment, the semiconductor material of the doped region 40 may contain a p-type dopant (e.g., boron) that provides p-type electrical conductivity. In an embodiment, a portion of the semiconductor layer 26 immediately adjacent to the doped region 40 and an underlying portion of the pad 24 may be implanted with the p-type dopant due to overlap of the implantation mask.

The doped region 42 may be formed by, for example, ion implantation with an implantation mask with an opening that determines an implanted area of the pad 24. The implantation mask may include a layer of photoresist applied by a spin-coating process, pre-baked, exposed to light projected through a photomask, baked after exposure, and developed with a chemical developer to define the opening over the area of the pad 24 to be implanted. The implantation conditions (e.g., ion species, dose, kinetic energy) may be selected to tune the electrical and physical characteristics of the doped region 42. The implantation mask may be stripped after forming the doped region 42. In an embodiment, the semiconductor material of the doped region 42 may contain an n-type dopant (e.g., phosphorus and/or arsenic) that provides n-type electrical conductivity. In an embodiment, a portion of the semiconductor layer 26 immediately adjacent to the doped region 42 and an underlying portion of the pad 24 may be implanted with the n-type dopant due to overlap of the implantation mask.

A portion of the pad 24 beneath the semiconductor layer 26 may be comprised of intrinsic semiconductor material, such as intrinsic silicon, that is not doped by the ion implantation forming the doped regions 40, 42. The longitudinal axis 21 of the tapered section 20 may be aligned with the intrinsic portion of the pad 24. In an embodiment, the intrinsic portion of the pad may extend from the side edge 23 of the pad 24 to the side edge 25 of the pad 24. The doped region 40, the intrinsic semiconductor materials of the semiconductor layer 26 and the portion of the pad 24 beneath the semiconductor layer 26, and the doped region 42 may define a lateral p-i-n diode structure that operates as the photodetector 14.

A heavily-doped region 41 may be formed by a masked ion implantation in a portion of the doped region 40 adjacent to the side edge 27, and a heavily-doped region 43 may be formed by a masked ion implantation in a portion of the doped region 42 adjacent to the side edge 29. The heavily-doped region 41 may be doped to the same conductivity type as the doped region 40 but at a higher dopant concentration. The heavily-doped region 43 may be doped to the same conductivity type as the doped region 42 but at a higher dopant concentration.

The doped region 40 wraps around the confining feature 30 with a portion of the doped region 40 arranged in the portion 33 of the pad 24 between the confining feature 30 and the semiconductor layer 26, a portion of the doped region 40 arranged in the portion 35 of the pad 24 that includes the heavily-doped region 41, and a portion of the doped region 40 arranged in a vertical direction between the confining feature 30 and the dielectric layer 16. The doped region 42 wraps around the confining feature 32 with a portion of the doped region 42 arranged in the portion 33 of the pad 24 between the confining feature 32 and the semiconductor layer 26, a portion of the doped region 42 arranged in the portion 35 of the pad 24 that includes the heavily-doped region 43, and a portion of the doped region 42 arranged in a vertical direction between the confining feature 32 and the dielectric layer 16.

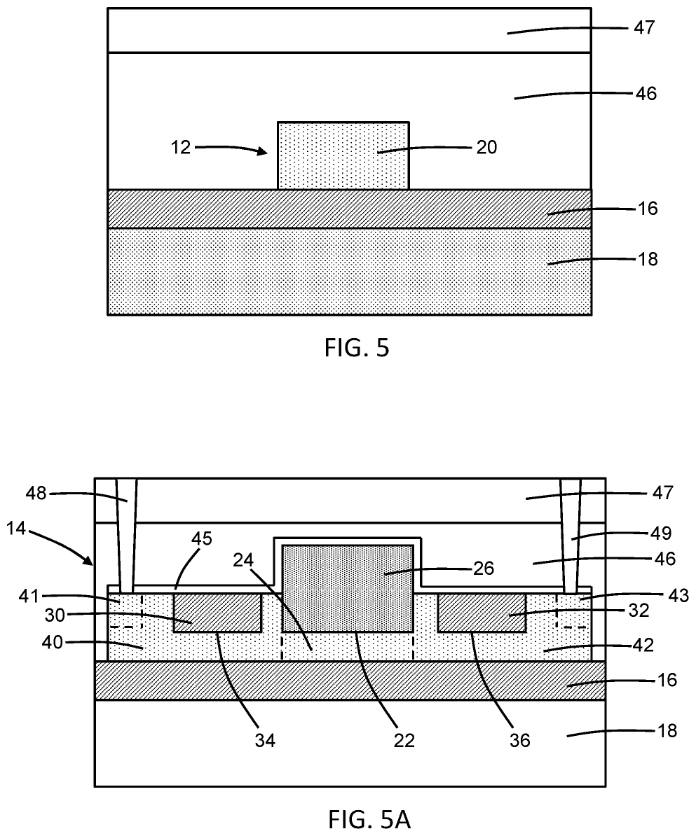

With reference to FIGS. 5, 5A in which like reference numerals refer to like features in FIGS. 3, 4, 4A and at a subsequent fabrication stage, a conformal dielectric layer 45 may be formed that extends across the pad 24 and semiconductor layer 26 following the topography created by the semiconductor layer 26. The conformal dielectric layer 45 may be comprised of a dielectric material, such as silicon nitride, and includes portions that overlap with the confining features 30, 32. The conformal dielectric layer 45 is comprised of a dielectric material that is different from the dielectric material of the confining features 30, 32. An additional conformal dielectric layer (not shown) comprised of a dielectric material, such as silicon dioxide, may be disposed between the semiconductor layer 26 and the conformal dielectric layer 45.

Dielectric layers 46, 47 are formed on the waveguide core 12 and the photodetector 14. In an embodiment, the dielectric layers 46, 47 may be comprised of a dielectric material, such as silicon dioxide, that has a lower refractive index than the material of the waveguide core 12. The dielectric layer 46 may be deposited and planarized, and the dielectric layer 47 may be deposited on the planarized dielectric layer 46. The dielectric layer 46 is separated from the confining features 30, 32 by the conformal dielectric layer 45, which is comprised of a different dielectric material than the dielectric layer 46.

Contacts 48 may be formed that penetrate fully through the conformal dielectric layer 45 and the dielectric layers 46, 47 to land on the heavily-doped region 41, and contacts 49 may be formed that penetrate fully through the conformal dielectric layer 45 and the dielectric layers 46, 47 to land on the heavily-doped region 43. The heavily-doped region 41 electrically couples the contacts 48 to the doped region 40 with a reduced contact resistance. The heavily-doped region 43 electrically couples the contacts 49 to the doped region 42 with a reduced contact resistance. The contacts 48, 49 may be comprised of a metal, such as tungsten. The doped regions 40, 42 may be biased through the contacts 48, 49.

In use, light (e.g., laser light) propagates in the waveguide core 12 toward the photodetector 14 and is coupled from the tapered section 20 of the waveguide core 12 to the semiconductor layer 26 of the photodetector 14. The waveguide core 12 may support propagation of light with transverse-electric polarization, transverse-magnetic polarization, or a combination of both. In an embodiment, the light received by the photodetector 14 may be modulated as an optical signal. The semiconductor layer 26 absorbs photons of the light and converts the absorbed photons into charge carriers by the photoelectric effect. The biasing of the doped regions 40, 42 causes the charge carriers to be collected and output to provide, as a function of time, a measurable photocurrent.

The confining features 30, 32 may enhance the optical confinement in the vicinity of the semiconductor layer 26 such that the efficiency of the photodetector 14 is improved. The addition of the confining features 30, 32 may mitigate the tradeoff between responsivity and bandwidth for the photodetector 14 such that one of these performance metrics of the photodetector 14 can be improved without any significant sacrifice of the other performance metric.

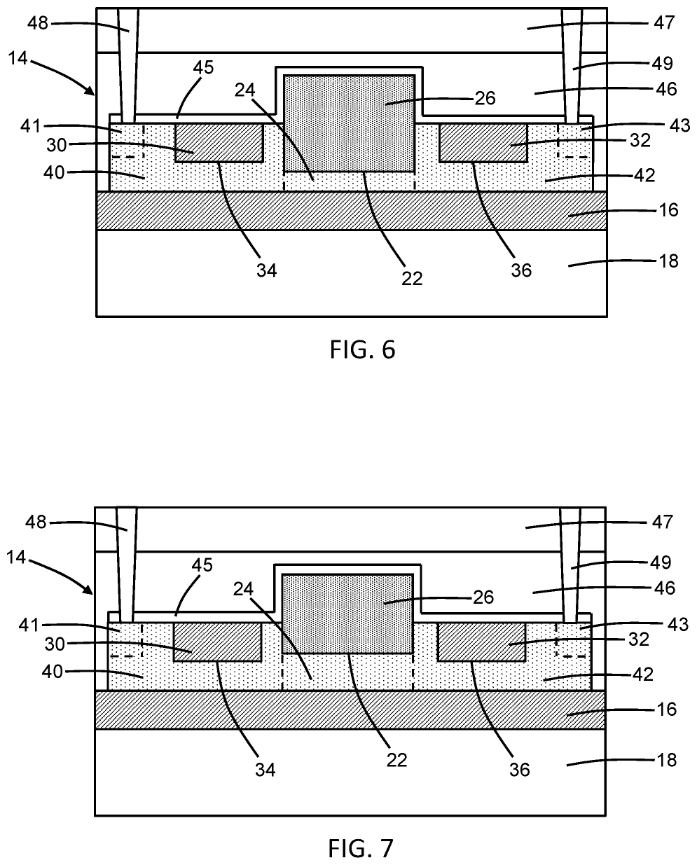

With reference to FIG. 6 and in accordance with alternative embodiments, the structure 10 may be modified such that the trench 22 and the trenches 34, 36 have unequal depths. In an embodiment, the depth of the trench 22 relative to the top surface 28 of the pad 24 may be increased relative to the depths of the trenches 34, 36, also relative to the top surface 28, to provide the unequal depths. The result is that the semiconductor layer 26 extends in the pad 24 to a greater depth compared to the depths to which the confining features 30, 32 extend. Another consequence is that the trench 22 may be formed by a different set of lithography and etching processes than the set of lithography and etching processes used to form the trenches 34, 36.

With reference to FIG. 7 and in accordance with alternative embodiments, the structure 10 may be modified to decrease the depth of the trench 22 in comparison to the depths of the trenches 34, 36 to provide the unequal depths. The result of the shallower trench 22 is that the semiconductor layer 26 extends in the pad 24 to a shallower depth compared to the depths to which the confining features 30, 32 extend in the trenches 34, 36.

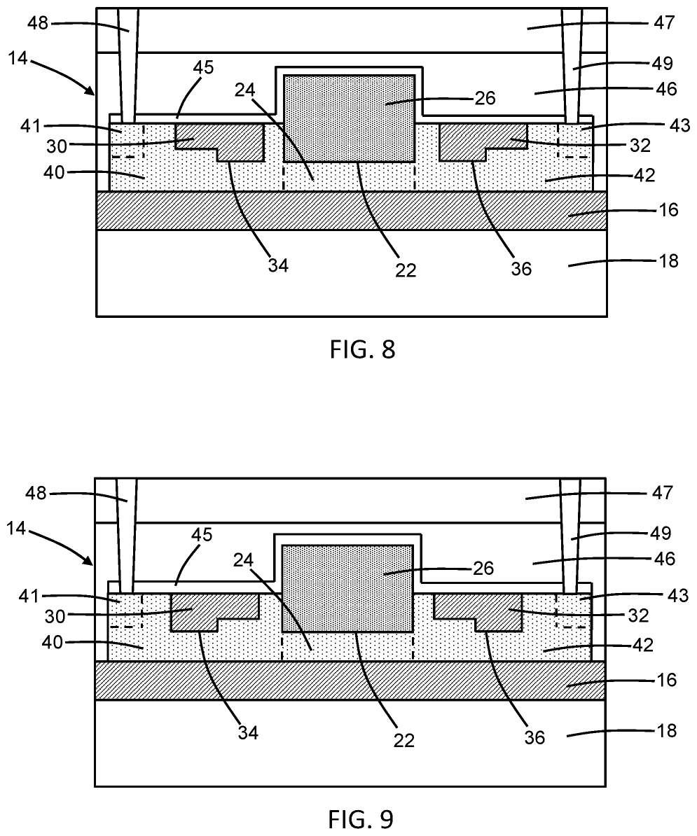

With reference to FIG. 8 and in accordance with alternative embodiments, the structure 10 may be modified such that the confining features 30, 32 and the trenches 34, 36 holding the confining features 30, 32 each include portions that extend to multiple depths relative to the top surface 28 of the pad 24. In an embodiment, the deeper portion of the confining feature 30 and the deeper portion of the confining feature 32 may be disposed adjacent to the semiconductor layer 26. The deeper portions of the confining features 30, 32 are disposed between the shallower portions of the confining features 30, 32 and the semiconductor layer 26.

With reference to FIG. 9 and in accordance with alternative embodiments, the structure 10 may be modified such that the shallower portion of the confining feature 30 and the shallower portion of the confining feature 32 are disposed adjacent to the semiconductor layer 26. The shallower portions of the confining features 30, 32 are disposed between the deeper portions of the confining features 30, 32 and the semiconductor layer 26.

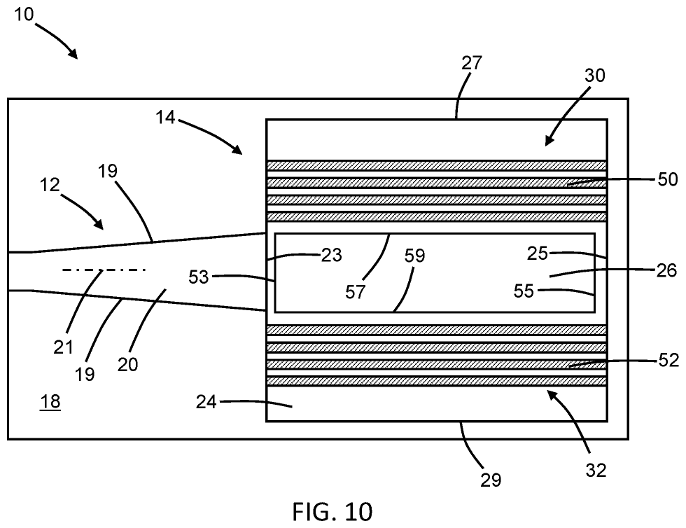

With reference to FIG. 10 and in accordance with alternative embodiments, the structure 10 may be modified such that the confining feature 30 includes multiple segments 50 and the confining feature 32 includes multiple segments 52. In an embodiment, the segments 50 of the confining feature 30 and the segments 52 of the confining feature 30 may extend from the side edge 23 of the pad 24 to the side edge 25 of the pad 24. In an embodiment, the segments 50, 52 may extend parallel to the sidewalls 57, 59 of the semiconductor layer 26. Portions of the pad 24 are disposed in the spaces between the segments 50 and in the spaces between the segments 52.

In an embodiment, the pitch and duty cycle of the segments 50, 52 may be uniform to define a periodic arrangement. In alternative embodiments, the pitch and/or the duty cycle of the segments 50, 52 may be apodized (i.e., non-uniform) to define an aperiodic arrangement. The segments 50, 52 may be dimensioned and positioned at small enough pitch to define a sub-wavelength grating that does not radiate or reflect light at a wavelength of operation. The dielectric material of the segments 50, 52 and the material of the portions of the pad 24 between the segments 50, 52 may define respective metamaterial structures in which the material constituting the portions of the pad 24 has a higher refractive index than the dielectric material of the segments 50, 52. The metamaterial structures can each be treated as a homogeneous material having an effective refractive index that is intermediate between the refractive index of the material constituting the portions of the pad 24 between the segments 50, 52 and the refractive index of the dielectric material constituting the segments 50, 52.

Processing continues as previously described to complete the structure 10 by performing the subsequent fabrication stages of the processing method.

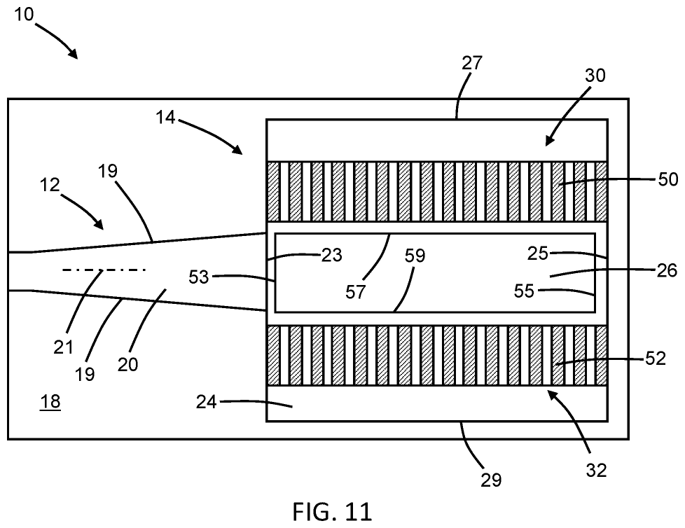

With reference to FIG. 11 and in accordance with alternative embodiments, the structure 10 may be modified such that the segments 50 of the confining feature 30 are oriented non-parallel to the sidewall 57 of the semiconductor layer 26, and the segments 52 of the confining feature 32 are oriented non-parallel to the sidewall 59 of the semiconductor layer 26. In an embodiment, the segments 50 of the confining feature 30 may be oriented perpendicular to the sidewall 57 of the semiconductor layer 26, and the segments 52 of the confining feature 32 may be oriented perpendicular to the sidewall 59 of the semiconductor layer 26.

Processing continues as previously described to complete the structure 10 by performing the subsequent fabrication stages of the processing method.

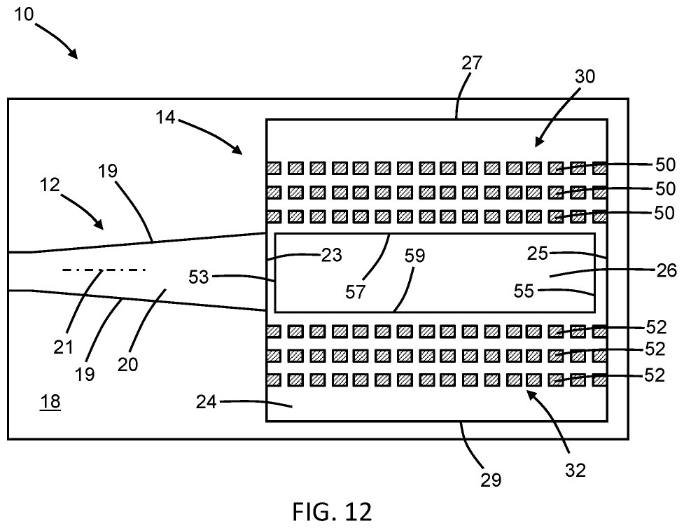

With reference to FIG. 12 and in accordance with alternative embodiments, the structure 10 may be modified such that the segments 50 of the confining feature 30 are arranged in the rows and columns of a two-dimensional array adjacent to the sidewall 57 of the semiconductor layer 26, and the segments 52 of the confining feature 32 are arranged in the rows and columns of a two-dimensional array adjacent to the sidewall 59 of the semiconductor layer 26.

Processing continues as previously described to complete the structure 10 by performing the subsequent fabrication stages of the processing method.

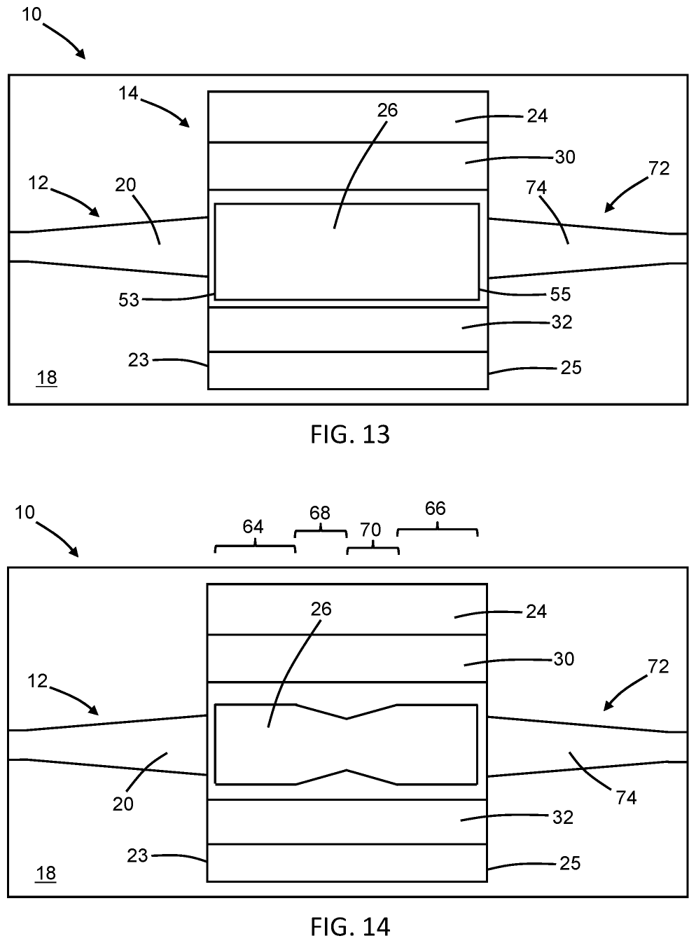

With reference to FIG. 13 and in accordance with alternative embodiments, a waveguide core 72 may include a tapered section 74 that is positioned adjacent to the side edge 25 of the pad 24 of the photodetector 14 that is opposite from the side edge 23 and positioned adjacent to a sidewall 55 of the semiconductor layer 26 that is opposite from the sidewall 53. The tapered section 74 of the waveguide core 72 may be similar or identical to the tapered section 20 of the waveguide core 12. In an embodiment, the waveguide core 72 may be comprised of the same material as the waveguide core 12.

The waveguide core 72 may supply another input to the photodetector 14 in addition to the input provided by the waveguide core 12. For example, the total power delivered to the photodetector 14 may be split between the input provided by the waveguide core 12 and the input provided by the waveguide core 72. The confining features 30, 32 may enhance the optical confinement for light supplied to the photodetector 14 by the tapered section 74 similar to the enhancement provided by the confining features 30, 32 for light supplied the photodetector 14 by the tapered section 20.

With reference to FIG. 14 and in accordance with alternative embodiments, the semiconductor layer 26 of the photodetector 14 may be modified to have a non-rectangular shape. In an embodiment, the semiconductor layer 26 may include a non-tapered section 64 adjacent to the tapered section 20 of the waveguide core 12, a non-tapered section 66 adjacent to the tapered section 74 of the waveguide core 72, and tapered sections 68, 70 that are arranged between the non-tapered section 64 and the non-tapered section 66. The tapered sections 68, 70 may be configured to taper in opposite directions and to adjoin at their respective narrow ends with the wide end of the tapered section 68 adjoining the non-tapered section 64 and the wide end of the tapered section 70 adjoining the non-tapered section 66. The tapered section 68 has a width dimension that decreases with decreasing distance from the tapered section 70, and the tapered section 70 has a width dimension that decreases with decreasing distance from the tapered section 68.

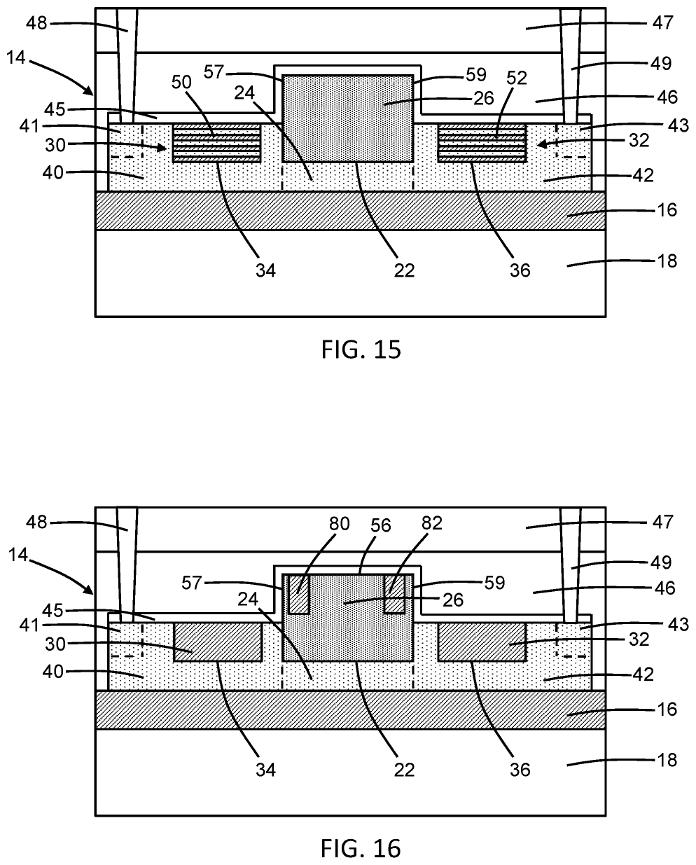

With reference to FIG. 15 and in accordance with alternative embodiments, the structure 10 may be modified such that the segments 50 of the confining feature 30 are arranged in a layer stack adjacent to the sidewall 57 of the semiconductor layer 26, and the segments 52 of the confining feature 32 are arranged in a layer stack adjacent to the sidewall 59 of the semiconductor layer 26. Dielectric layers 60 comprised of a dielectric material, such as silicon dioxide, may be disposed in the spaces between adjacent segments 50 and in the spaces between adjacent segments 52. The dielectric layers 60 alternate in the layer stack with the segments 50 and alternate in the layer stack with the segments 52. In an embodiment, the segments 50 of the confining feature 30 may be doped to have the same conductivity type as the doped region 40, and the segments 52 of the confining feature 32 may be doped to have the same conductivity type as the doped region 42.

With reference to FIG. 16 and in accordance with alternative embodiments, the semiconductor layer 26 may be modified to add confining features 80, 82 that are similar to the confining features 30, 32. The confining feature 80, which is formed in a trench patterned in the semiconductor layer 26, may be disposed adjacent to the sidewall 57 of the semiconductor layer 26. The confining feature 82, which is also formed in a trench patterned in the semiconductor layer 26, may be disposed adjacent to the sidewall 59 of the semiconductor layer 26. The confining features 80, 82 extend from the top surface 56 of the semiconductor layer 26 into the bulk of the semiconductor layer 26 and penetrate partially through the semiconductor layer 26.

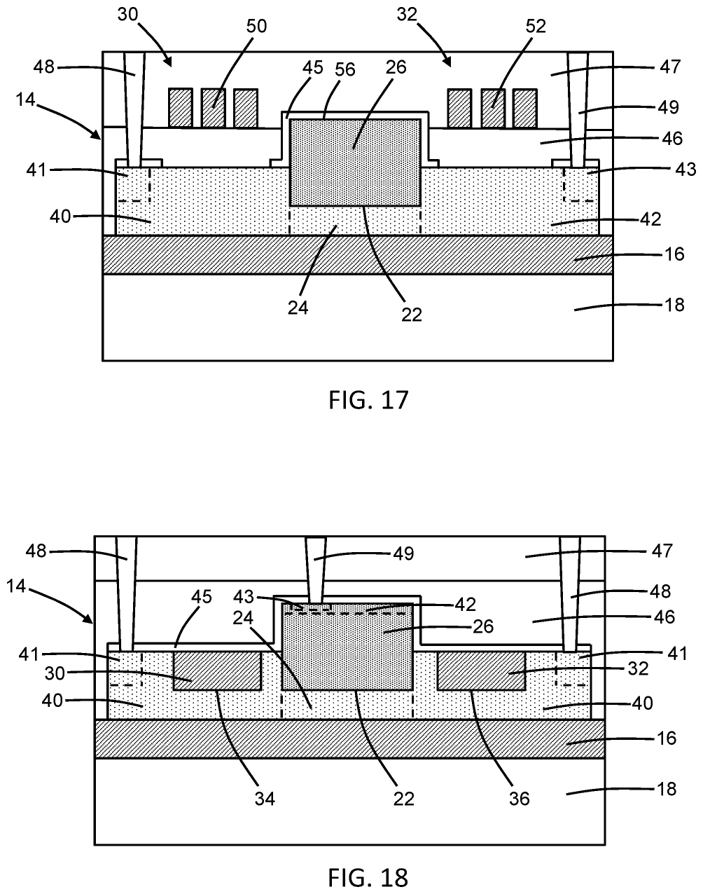

With reference to FIG. 17 and in accordance with alternative embodiments, the structure 10 may be modified such that the segments 50 of the confining feature 30 are arranged above the doped region 40 and adjacent to the sidewall 57 of the semiconductor layer 26, and the segments 52 of the confining feature 32 are arranged above the doped region 42 and adjacent to the sidewall 59 of the semiconductor layer 26. The segments 50, 52 may be comprised of a dielectric material, such as silicon nitride. Portions of the conformal dielectric layer 45 between the segments 50, 52 may be removed. In an embodiment, the segments 50, 52 may have an upper portion that is disposed above the top surface 56 of the semiconductor layer 26 and a lower portion that is disposed below the top surface 56 of the semiconductor layer 26. In an embodiment, the segments 50, 52 may be positioned entirely above the top surface 56 of the semiconductor layer 26. The segments 50, 52 may be arranged in an array as shown in FIG. 10 or FIG. 12, or may alternatively be arranged in an array as shown in FIG. 11.

With reference to FIG. 18 and in accordance with alternative embodiments, the structure 10 may be modified such that the photodetector 14 has a vertical arrangement instead of a lateral arrangement. Specifically, in the vertical arrangement, the doped region 40 and heavily-doped region 41 may be arranged in the pad 24 on both sides of the semiconductor layer, and the doped region 42 and heavily-doped region 43 may be arranged in the semiconductor layer 26.

In an alternative embodiment, the structure 10 may be configured with the doped region 40 in the pad 24 only adjacent to one side of the semiconductor layer 26. In an alternative embodiment, the photodetector 14 may be configured as an avalanche photodetector that includes an intrinsic semiconductor region in the pad 24 defining a multiplication region and an additional doped region in the pad 24 defining a charge control region.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate a range of +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure for a photonics chip, the structure comprising:
a photodetector including a pad and a semiconductor layer positioned on the pad, the semiconductor layer having a first sidewall, the pad comprising a semiconductor material, and the pad including a top surface and a first side edge;
a waveguide core including a tapered section adjacent to the first side edge of the pad; and
a first confining feature in the pad adjacent to the first sidewall of the semiconductor layer, the first confining feature extending below the top surface of the pad, and the first confining feature comprising a dielectric material.

2. The structure of claim 1 wherein the semiconductor layer has a second sidewall opposite from the first sidewall, and further comprising:
a second confining feature in the pad adjacent to the second sidewall of the semiconductor layer, the second confining feature extending below the top surface of the pad, and the second confining feature comprising the dielectric material.

3. The structure of claim 1 wherein the first confining feature is positioned in a trench in the pad, and the trench has a uniform depth relative to the top surface.

4. The structure of claim 1 wherein the first confining feature is positioned in a trench in the pad, the trench has a first portion and a second portion, the first portion of the trench is disposed adjacent to the first sidewall, and the first portion of the trench has a shallower depth relative to the top surface than the second portion of the trench.

5. The structure of claim 1 wherein the first confining feature is positioned in a trench in the pad, the trench has a first portion and a second portion, the first portion of the trench is disposed adjacent to the first sidewall, and the second portion of the trench has a shallower depth relative to the top surface than the first portion of the trench.

6. The structure of claim 1 wherein the first confining feature is positioned in a first trench in the pad, the pad includes a second trench, the semiconductor layer is positioned in the second trench, and the first trench and the second trench extend to equal depths in the pad.

7. The structure of claim 1 wherein the first confining feature is positioned in a first trench in the pad, the pad includes a second trench, the semiconductor layer is positioned in the second trench, and the first trench and the second trench extend to unequal depths in the pad.

8. The structure of claim 1 further comprising:
a dielectric layer,
wherein the pad and the waveguide core are disposed on the dielectric layer, and the first confining feature is positioned in a first trench that penetrates partially through the pad toward the dielectric layer.

9. The structure of claim 1 wherein the pad includes a portion between the first confining feature and the semiconductor layer.

10. The structure of claim 1 wherein the pad includes a doped region adjacent to the first sidewall of the semiconductor layer, and the first confining feature is disposed in the doped region of the pad.

11. The structure of claim 1 wherein the pad includes a second side edge opposite from the first side edge, and the first confining feature extends from the first side edge to the second side edge.

12. The structure of claim 1 wherein the pad includes a trench, the first confining feature is positioned in the trench in the pad, and the trench in the pad has a length that is oriented parallel to the first sidewall of the semiconductor layer.

13. The structure of claim 1 wherein the pad includes a plurality of trenches, and the dielectric material of the first confining feature is disposed in the plurality of trenches in the pad.

14. The structure of claim 1 wherein the first confining feature comprises a metamaterial structure.

15. The structure of claim 1 wherein the first confining feature comprises a first plurality of layers and a second plurality of layers that alternative with the first plurality of layers in a layer stack.

16. The structure of claim 1 further comprising:
a first dielectric layer that overlaps with the first confining feature.

17. The structure of claim 16 further comprising:
a second dielectric layer on the first dielectric layer;
a doped region in the pad; and
a contact extending through the first dielectric layer and the second dielectric layer to the doped region.

18. The structure of claim 17 wherein the first confining feature is positioned in the doped region.

19. The structure of claim 16 wherein the dielectric material of the first confining feature is silicon dioxide, and the first dielectric layer comprises silicon nitride.

20. A method of forming a structure for a photonics chip, the method comprising:
forming a photodetector that includes a pad comprising a semiconductor material
forming a semiconductor layer that is positioned on the pad;
forming a waveguide core that includes a tapered section adjacent to a side edge of the pad; and
forming a confining feature in the pad adjacent to a sidewall of the semiconductor layer, wherein the confining feature extends below a top surface of the pad, and the confining feature comprises a dielectric material.
